(19) United States
(12) Patent Application Publication
(10) Pub. No.: US 2024/0339343 A1
(43) Pub. Date: Oct. 10, 2024

(54) SINTERING PRESS

(71) Applicant: AMX - AUTOMATRIX S.R.L., Roe' Volciano (Brescia) (IT)

(72) Inventor: Nicola SCHIVALOCCHI, Roe' Volciano (Brescia) (IT)

(21) Appl. No.: 18/577,814

(22) PCT Filed: Dec. 28, 2021
(86) PCT No.: PCT/IB2021/062386

§ 371 Date: Jan. 9, 2024

(30) Foreign Application Priority Data
Jul. 13, 2021 (IT) 102021000018458

(51) Int. Cl. H01L 21/67; B30B 15/00; B30B 15/02

(52) U.S. Cl. CPC H01L 21/67126; B30B 15/007; B30B 15/0094; B30B 15/026; H01L 21/67121

(57) ABSTRACT

A press for pre-sintering or sintering silicon wafers that has a lower block and an upper block is provided. The lower block has a lower base and a lower plate. The lower plate rests exclusively on a top surface of a body of at least three compression load cells. The load cell bodies are supported by the lower base so that the top surfaces are substantially coplanar with each other.

This invention relates to the field of processes for manufacturing silicon wafers and relates in particular to a press suitable to perform pre-sintering or sintering of said silicon wafers.

Pre-sintering (also known by the term “wafer lamination”) and sintering (“wafer sintering”) are two stages of the production process of silicon wafers that can be achieved with the same dedicated press and that differ substantially from each other in the working parameters of the pressing operation, in particular the temperature.

According to the preamble of claim 1, a press for

pre-sintering or sintering silicon wafers comprises a lower block and an upper block, wherein the lower block comprises a lower base and a lower plate supported by the lower base and forming a lower surface for supporting the silicon wafers to be sintered. The upper block comprises an upper plate forming an upper surface facing the upper surface.

The press is provided with actuator means suitable to translate the lower plate and/or the upper plate between an inactive position of mutual separation and an active position wherein the upper surface exerts a predetermined pressure on the silicon wafers present on the lower surface.

Pre-sintering and sintering of silicon wafers should satisfy the following assumptions to be considered reliable:
freely programmable process temperature from approximately 100° C. to approximately 350° C.;
process temperature uniformly distributed over the processed wafer with a permissible deviation of approximately +/−3° C.;
freely programmable process pressure from approximately 1 MPa to approximately 40 MPa;
process pressure uniformly distributed over the processed wafer with a permissible deviation of approximately +/−0.5 MPa.

To satisfy these requirements, the press should ensure:
strength and absolute rigidity of the lower and upper surfaces;
absolute parallelism between the lower and upper surfaces.

An object of this invention is to propose a press of the above-described type capable of satisfying the requirements cited above.

Said object is achieved with a pre-sintering or sintering press according to claim 1.

The features and advantages of the press according to the invention will however become apparent from the following description of its preferred example embodiments, given by way of non-limiting example, with reference to the accompanying figures, wherein:

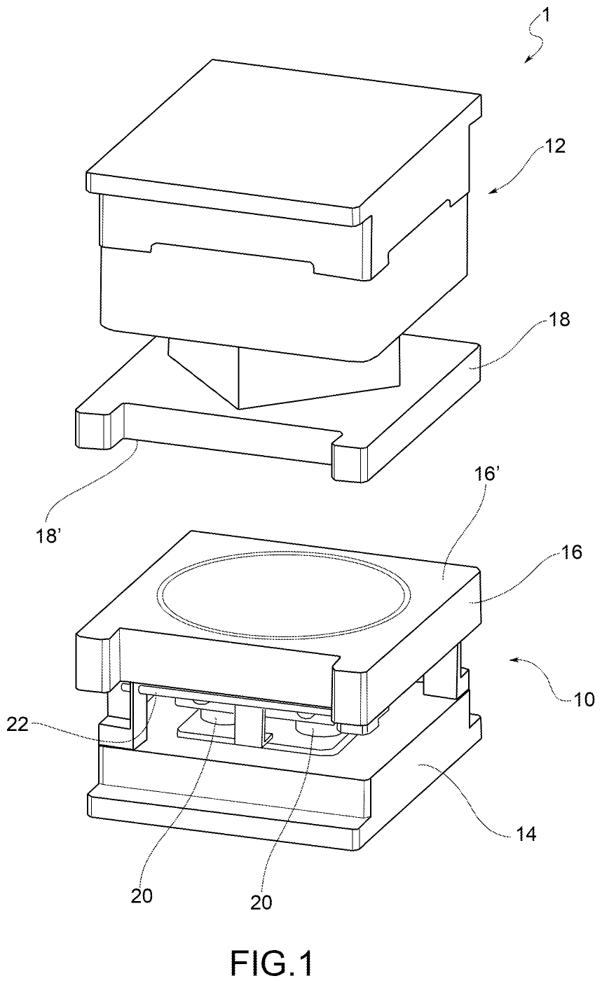

FIG. 1 is a perspective view of a press according to the invention, in one embodiment;

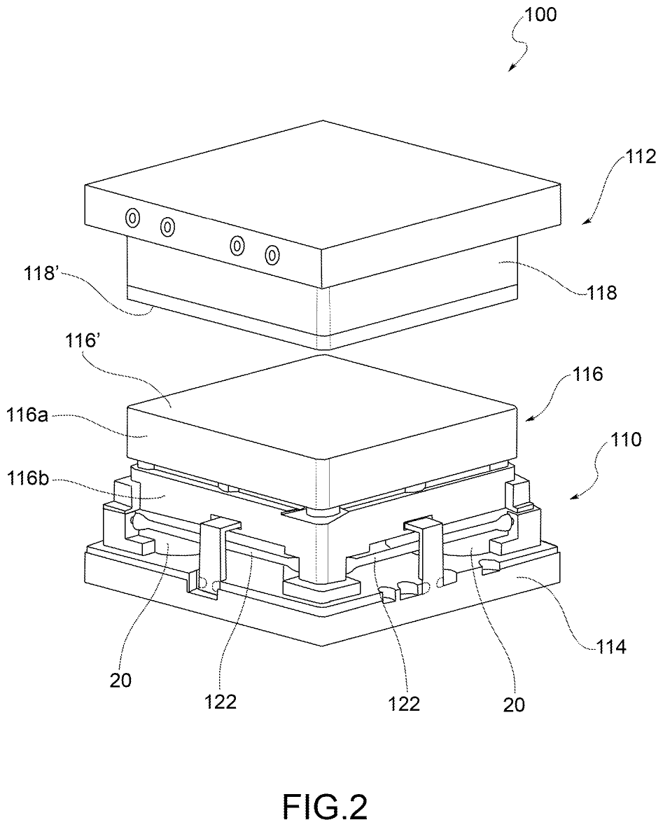

FIG. 2 is a perspective view of a press according to the invention, in another embodiment;

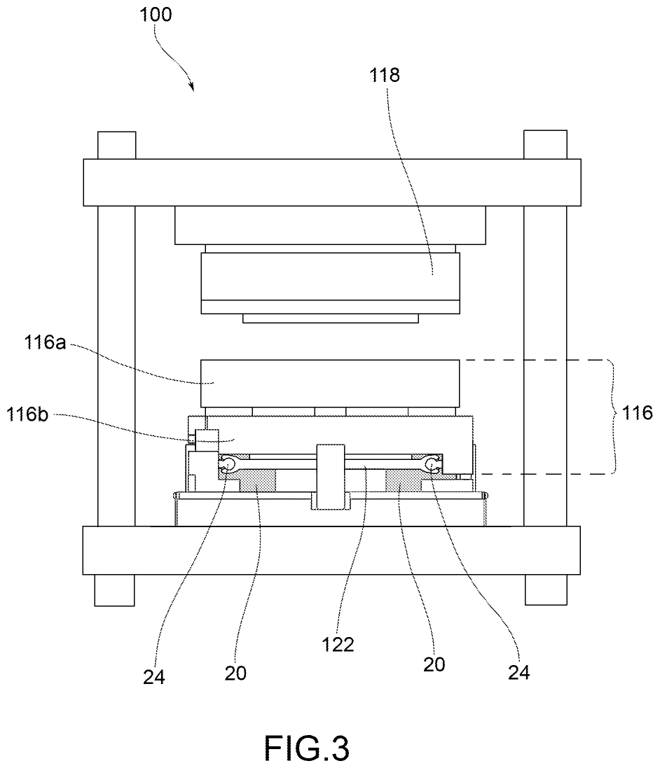

FIG. 3 is a schematic elevation view of the press in FIG. 2.

In the following description, elements common to the various embodiments shall be indicated with the same reference numbers.

In reference to the accompanying drawings, 1; 100 indicates in its entirety a press for pre-sintering or sintering silicon wafers.

According to a general embodiment, the press 1; 100 comprises a lower block 10; 110 and an upper block 12; 112.

The lower block 10; 110 comprises a lower base 14; 114 and a lower plate 16; 116 supported by the lower base and forming a lower surface 16′; 116′ for supporting silicon wafers to be pre-sintered or sintered.

In some embodiments, as illustrated in the drawings, the lower plate 16; 116 can comprise two overlapping, rigidly connected plate portions (e.g., indicated as 116a and 116b in FIGS. 2 and 3), the upper portion 116a, on which the silicon wafers rest, being a heated plate, the upper portion 116b, in contact with the load cells, being maintained at a lower temperature.

The upper block 12; 112 comprises an upper plate 18; 118 forming an upper surface 18′; 118′ facing the lower surface 16′; 116′.

The press is provided with actuator means, for example, hydraulic or electric, suitable to translate the lower plate 16; 116 and/or the upper plate 18; 118 between an inactive position of mutual separation and an active position wherein the upper surface exerts a predetermined pressure on the silicon wafers on the lower surface.

According to an aspect of the invention, the lower plate 16; 116 rests only on the top surface of the body 20 of at least three compression load cells supported by the lower base 14; 114 so that said top surfaces are substantially coplanar with one another.

In the embodiment of FIG. 1, the lower plate 16 rests on the bodies 20 of three load cells, for example arranged at the vertices of an equilateral triangle.

In the embodiment of FIGS. 2 and 3, the lower plate 116 rests on the bodies 20 of four load cells, for example arranged at the vertices of a square.

The number of load cell bodies can depend on the surface to be sintered and/or on the pressure applied to the silicon wafers.

The body 20 of the load cells is suitable to deflect in such a way as to allow the lower plate to pivot to compensate for any non-parallelism between the lower surface and the upper surface and/or any non-parallelism between the upper surface of the silicon wafers and the lower and/or upper surface.

Therefore, the use of the body 20, or casing, of the load cells as the only supporting element of the lower plate allows perfect adhesion between the lower surface 16′; 116′ and the upper surface 18′; 118′.

In one embodiment, the load cell body 20 is devoid of a pressure sensor. Therefore, in this case, the load cells are used exclusively as pivoting support means.

In other embodiments, the load cell body 20 is equipped with a pressure sensor, for example a strain gauge, suitable to detect the pressure exerted by the upper surface on the silicon wafers.

In this case, therefore, the load cells perform both the function of pivoting support for the lower plate and the function of pressure sensors.

In one embodiment, the load cell bodies 20 have substantially the same height. For example, the top surfaces of the load cell bodies are simultaneously subjected to a grinding process so that the bodies have the same height.

In one embodiment, the load cell bodies are identical to each other.

In some embodiments, the lower plate 16; 116 is held in place by means of connecting bars 22; 122, for example adjustable deflection bars. In other words, the connecting bars 22; 122 prevent the lower plate 16; 116, which, 1 resting exclusively on the load cell bodies 20, would not be subjected to other constraints, from translating in an undesirable way with respect to the load cell body 20.

For example, in the case of the rectangular-shaped lower block 10; 110, at least two opposite sides of the lower plate 16; 116 are connected to respective opposite sides of the lower base 14; 114 by means of respective connecting bars 22; 122. Specifically, each connecting bar 22; 122 connects a vertex of the bottom plate 16; 116 with the opposite vertex of the respective side of the lower base 14; 114. Preferably, moreover, the bars 22; 122 of opposite sides of the lower block are connected in an opposite manner to their respective vertices. In other words, the two opposite bars connect opposite vertices of the lower plate (i.e., at the ends of the diagonal of the rectangle that defines the perimeter of the lower plate seen in plan view) to opposite vertices of the lower base.

In one embodiment, the connecting bars 22; 122 are connected to the lower plate 16; 116 and to the lower base 14; 114 by means of ball joints 24, so as to allow for any inclinations of the lower plate with respect to the lower base without affecting the interaction between the lower plate and the load cell body.

In one embodiment, the load cell body has a maximum deflection of about 0.5 mm at the nominal load.

For example, the press can compensate for non-parallelism up to approximately 0.3 mm from edge to edge of the surface defined by the centerlines of the load cells.

To the embodiments of the press according to the invention, in order to meet contingent needs, a person skilled in the art may make a number of changes, adaptations, and substitutions of elements with other functionally equivalent ones without departing from the scope of the following claims. Each of the features described as belonging to a possible embodiment may be obtained independently of the other described embodiments.

1-10. (canceled)

11. A press for pre-sintering or sintering silicon wafers, comprising a lower block and an upper block, wherein the lower block comprises a lower base and a lower plate supported by the lower base and forming a lower surface for supporting the silicon wafers to be sintered, and wherein the upper block comprises an upper plate forming an upper surface facing the lower surface, the press comprising actuator means suitable to translate the lower plate and/or the upper plate between an inactive position of mutual separation and an active position in which the upper surface applies a predetermined pressure to the silicon wafers present on the lower surface,
wherein the lower plate rests only on a top surface of a body of at least three compression load cells, wherein the body of the at least three compression load cells is the only supporting element of the lower plate, the load cell bodies being supported by the lower base so that the top surfaces are substantially coplanar with one another.

12. The press of claim 11, wherein the load cells body is devoid of a pressure sensor.

13. The press of claim 11, wherein the load cells body is provided with a pressure sensor suitable to detect the pressure applied by the upper surface to the silicon wafers.

14. The press of claim 11, wherein the load cells body is suitable to deflect to allow the lower plate to pivot so as to compensate for any non-parallelism between the lower surface and the upper surface and/or any non-parallelism between an upper surface of the silicon wafers and the lower and/or upper surface.

15. The press of claim 11, wherein the load cells bodies have substantially a same height.

16. The press of claim 11, wherein the lower plate is held in place by connecting bars that connect the lower plate to the lower base.

17. The press of claim 16, wherein at least two opposite sides of the lower plate are connected to respective opposite sides of the lower base by respective connecting bars.

18. The press of claim 17, wherein each connecting bar connects a vertex of the lower plate to an opposite vertex of the respective side of the lower base.

19. The press of claim 16, wherein the connecting bars are connected to the lower plate and to the lower base by ball joints.

20. The press of claim 11, wherein the at least three compression load cells have a maximum deflection of 0.5 mm at a nominal load.
